(19) United States
(12) Patent Application Publication
(10) Pub. No.: US 2025/0085328 A1
(43) Pub. Date: Mar. 13, 2025

(54) PRECISE FAULT LOCATION APPARATUS AND METHOD FOR COLLECTOR LINE IN ONSHORE WIND FARM

(71) Applicant: Hunan University of Science and Technology, Xiangtan City (CN)

(72) Inventors: Zhaohua LIU, Xiangtan City (CN); Zhijian YI, Xiangtan City (CN); Junjie LONG, Xiangtan City (CN); Lei CHEN, Xiangtan City (CN); Mingyang LV, Xiangtan City (CN); Ming LI, Xiangtan City (CN)

(21) Appl. No.: 18/820,679

(22) Filed: Aug. 30, 2024

(30) Foreign Application Priority Data
Sep. 8, 2023 (CN) 202311157926.7

(51) Int. Cl. G01R 31/11; G01R 31/08

(52) U.S. Cl. CPC G01R 31/11; G01R 31/083

(57) ABSTRACT

Provided is a precise fault location method for a collector line in an onshore wind farm. The method includes sends sending, by a slave unit, a high-voltage pulse signal at the beginning of a collector line to measure a cable length at a fault point of the collector line. A master unit and the slave unit send high-voltage pulse signals to each other to measure a cable length at any point on the collector line, thereby obtaining a geographical location corresponding to the cable length. The two measured cable lengths are compared and if the measured lengths are inconsistent, the master unit is moved, to make the two measured lengths equal with multiple approaches. In this case, the position of the master unit is a geographical location corresponding to the fault point.

### CROSS REFERENCE TO RELATED APPLICATION

This patent application claims the benefit and priority of Chinese Patent Application No. 2023111579267, filed with the China National Intellectual Property Administration on Sep. 8, 2023, the disclosure of which is incorporated by reference herein in its entirety as part of the present application.

### TECHNICAL FIELD

The present disclosure relates to the field of cable fault detection, and in particular, to a precise fault location apparatus and method for a collector line in an onshore wind farm.

### BACKGROUND

Wind power is the fastest-growing and largest green energy source in China, and it has become the focus of the country's new energy strategy. Onshore wind farms, as the largest group in terms of installed capacity, are generally located on high-altitude, high-wind-speed ridges or hills with harsh climate conditions and adverse geographical environments. Collector lines, crucial for ensuring the efficient and stable operation of wind turbines, face challenges in fault location, high maintenance cost, and issues such as turbine downtime and cascading shutdowns due to the multiple branch layouts and harsh working conditions of onshore wind farms, leading to significant economic losses. Therefore, high efficiency is the primary requirement for breakdown maintenance of onshore the collector line in a wind farm. However, the undulating and winding terrain during the installation of collector lines leads to characteristics such as looping, bending, and hidden orientations, resulting in significant deviations between the length and spatial position of the faulty cable. Existing apparatuses can only measure the distance of the cable fault but cannot precisely locate the spatial position of the fault, nor can they meet the high-efficiency operation and maintenance requirements.

Currently, common cable fault location methods include an impedance approach and a traveling wave approach. The impedance approach has advantages such as low equipment requirements and cost-effectiveness, and is often greatly affected by transient resistance, leading to less than ideal distance measurement results. Although researchers have improved and applied the impedance approach to multi-branch wind farms or distribution networks, this approach can only identify faulty sections without accurately pinpointing the fault location. Furthermore, for the collector line in a wind farm with numerous branches, fault location using the impedance approach results in increasing errors as the number of branches grows. The traveling wave approach can effectively mitigate the impact of transient resistance on distance measurement results, offering high accuracy and simplicity in operation. However, the traveling wave approach faces difficulties in identifying target wavefronts when encountering wavefront folding and reflection, and significant errors still arise from GPS synchronous clock issues.

In summary, most existing apparatuses can achieve good results in obtaining rough distance measurements but often struggle with precise fault location. The traveling wave approach remains mainstream for distance measurement, but due to the challenges of wavefront identification and asynchronous clocks, it cannot be applied effectively to the collector line in a wind farm. Therefore, existing apparatuses can only roughly locate faults in the collector line in a wind farm, and an apparatus capable of rapid and precise fault location has yet to be developed.

### SUMMARY

To solve the foregoing technical problems, the present disclosure provides a precise fault location apparatus for a collector line in an onshore wind farm that has a simple structure and high accuracy, and also provides a precise fault location method for a collector line in an onshore wind farm that is easy to operate and provides high positioning accuracy.

The technical solution to the aforementioned problems in the present disclosure is a precise fault location apparatus for a collector line in an onshore wind farm, which includes:
a slave unit installed at the beginning of a collector line cable, configured to input a high-voltage pulse signal S3 into a collector line, record an output time of the high-voltage pulse signal S3 and a time at which the high-voltage pulse signal S3 reaches the slave unit after being reflected from a fault point, calculate a time difference, and then multiply a wave speed by the time difference to obtain a cable length at the fault point; and also configured to input a high-voltage pulse signal S1 into the collector line, receive a high-voltage pulse signal S2 inputted by a master unit, and detect an input time of the high-voltage pulse signal S1 as well as a reception time of the high-voltage pulse signal S2; and
the master unit installed at a measurement point near the fault point of the collector line cable, configured to receive the high-voltage pulse signal S1 inputted by the slave unit, output the high-voltage pulse signal S2 to the slave unit, and detect a reception time of the high-voltage pulse signal S1 as well as an output time of the high-voltage pulse signal S2.

In the precise fault location apparatus for a collector line in an onshore wind farm, the master unit and the slave unit each include a microcontroller unit (MCU) module, a time calibration module, a signal detection module, a timing control module, a signal amplification, filtering, and steepening module, a Lora communication module, a high-frequency high-voltage pulse power output module, and a human-machine interface module. The MCU module is connected to the time calibration module, the signal detection module, the timing control module, the signal amplification, filtering, and steepening module, the Lora communication module, the lightweight high-frequency high-voltage pulse power output module, and the human-machine interface module. The high-frequency high-voltage pulse power output module is connected to the signal amplification, filtering, and steepening module.

The MCU module outputs a high-voltage pulse signal through a high-frequency high-voltage pulse power, and the high-voltage pulse signal is strengthened through the signal amplification, filtering, and steepening module and is output. The timing control module records an output time of the signal, and the signal detection module records a time at which the signal reaches the slave unit. The MCU module controls the output time of the signal, calculates a time difference, and subsequently calculates a cable length. The master unit and the slave unit communicate via the Lora communication module; interactive operations are performed through the human-machine interface module.

In the precise fault location apparatus for a collector line in an onshore wind farm, the MCU module uses an LPC1778 chip, and the time calibration module uses a 200 MHz crystal oscillator.

A precise fault location method for a collector line in an onshore wind farm includes the following steps:
1) inputting, by a slave unit, a high-voltage pulse signal S3 at the beginning of a cable, where the high-voltage pulse signal S3 is reflected back to the slave unit after encountering a fault point; calculating a time difference between input and reception of the pulse signal S3 by the slave unit; and multiplying a wave speed by the time difference to obtain a cable length L1 at the fault point;
2) inputting, by the slave unit, a high-voltage pulse signal S1 at the beginning of the cable, with an input time of the high-voltage pulse signal S1 denoted as T1;
3) receiving, by a master unit at a measurement point, the high-voltage pulse signal S1, with a reception time of the high-voltage pulse signal S1 denoted as T1′;
4) inputting, by the master unit, a high-voltage pulse signal S2 after receiving the high-voltage pulse signal S1, with an input time of the high-voltage pulse signal S2 denoted as T2′;
5) receiving, by the slave unit, the high-voltage pulse signal S2, with a reception time of the high-voltage pulse signal S2 denoted as T2;
6) calculating a time difference Δt₂ between the input of the high-voltage pulse signal S1 and the reception of the high-voltage pulse signal S2 by the slave unit; calculating a time difference Δt₁ between the reception of the high-voltage pulse signal S1 and the input of the high-voltage pulse signal S2 by the master unit; and calculating a cable length L2 at the measurement point and obtaining a corresponding geographical location; and
7) if L2 is not equal to L1, moving the master unit by 2 to 3 approaches, to make L2 equal to L1, where in this case, a position of the master unit is a geographical location of the fault point.

In the precise fault location apparatus for a collector line in an onshore wind farm, in step 6, Δt₁=T2′-T1′, and Δt₂=T2−T1. A traveling wave acquisition and calculation terminal uses Lora communication to receive the time difference, and calculates a length from any point on the cable to the beginning of the cable using the following formula: L=v(Δt₂−Δt₁)/2, where L is the cable length L2 at the measurement point, and v represents a propagation speed of the high-voltage pulse signal in the cable, known as the wave speed.

The present disclosure has the following beneficial effects:
1. The present disclosure achieves precise fault location in the collector line in a wind farm by using a slave unit for distance measurement, a master unit for calibration, and a collaborative approach between the master and slave units for precise fault location. By using two 200 MHz crystal oscillators instead of BeiDou/GPS timing devices, the issue of time asynchrony in dual-machine systems is resolved, thereby enhancing interference resistance.
2. The present disclosure achieves precise fault location in the collector line in a wind farm with multiple branches. Building upon the master-slave collaborative architecture, a dual-wave collaborative fault location scheme is proposed. By using two unidirectional waves to replace traditional reflective waves, the problem of peak identification in reflective waves is addressed, thereby improving distance measurement accuracy. By designing waveform amplification, filtering, and steepening circuits, the present disclosure enhances waveform signals to tackle errors caused by signal attenuation during transmission, thereby further enhancing distance measurement accuracy.

### BRIEF DESCRIPTION OF THE DRAWINGS

FIG. 1 is a flowchart of a location method according to the present disclosure;

FIG. 2 is a diagram of a dual-wave collaborative implementation designed according to the present disclosure;

FIG. 3 is a diagram of an MCU module according to the present disclosure;

FIG. 4 is a circuit diagram of dual-wave coordination according to the present disclosure;

FIG. 5 is a circuit diagram of an amplification, filtering, and steepening module according to the present disclosure;

FIG. 6 is a diagram of hardware execution logic according to the present disclosure;

FIG. 7 is a diagram of a software workflow according to the present disclosure;

FIG. 8 is a structural diagram of an analog multi-branch collector circuit according to the present disclosure;

FIGS. 9A-9B are waveform diagrams of an indoor experiment according to the present disclosure; and

FIGS. 10A-10B are waveform diagrams of an outdoor experiment according to the present disclosure.

### DETAILED DESCRIPTION OF THE EMBODIMENTS

The present disclosure is further described below with reference to accompanying drawings and embodiments.

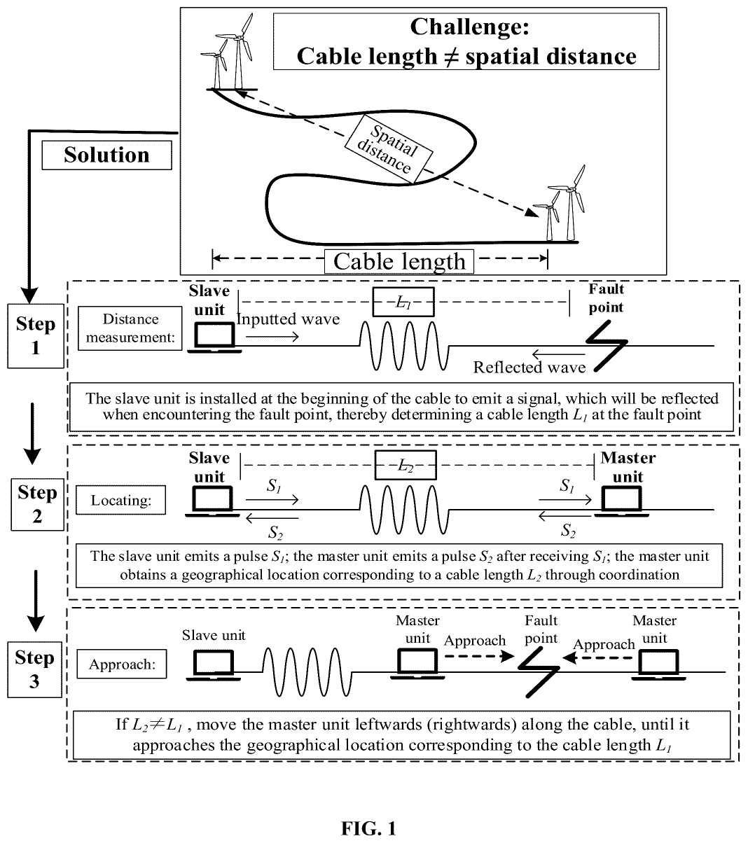

As shown in FIG. 1, a precise fault location apparatus for a collector line in an onshore wind farm includes:
a slave unit installed at the beginning of a collector line cable, configured to input a high-voltage pulse signal S3 into a collector line, record an output time of the high-voltage pulse signal S3 and a time at which the high-voltage pulse signal S3 reaches the slave unit after being reflected from a fault point, calculate a time difference, and then multiply a wave speed by the time difference to obtain a cable length at the fault point; and also configured to input a high-voltage pulse signal S1 into the collector line, receive a high-voltage pulse signal S2 inputted by a master unit, and detect an input time of the high-voltage pulse signal S1 as well as a reception time of the high-voltage pulse signal S2; and
the master unit installed at a measurement point near the fault point of the collector line cable, configured to receive the high-voltage pulse signal S1 inputted by the slave unit, output the high-voltage pulse signal S2 to the slave unit, and detect a reception time of the high-voltage pulse signal S1 as well as an output time of the high-voltage pulse signal S2.

The master unit and the slave unit each include an MCU module, a time calibration module, a signal detection module, a timing control module, a signal amplification, filtering, and steepening module, a Lora communication module, a high-frequency high-voltage pulse power output module, and a human-machine interface module. The MCU module is connected to the time calibration module, the signal detection module, the timing control module, the signal amplification, filtering, and steepening module, the Lora communication module, the lightweight high-frequency high-voltage pulse power output module, and the human-machine interface module. The high-frequency high-voltage pulse power output module is connected to the signal amplification, filtering, and steepening module.

The MCU module outputs a high-frequency pulse signal through a high-frequency high-voltage pulse power, and the high-frequency pulse signal is strengthened through the amplification, filtering, and steepening module and is output. The timing control module records an output time of the signal, and the signal detection module records a time at which the signal reaches the slave unit. The MCU module controls the output time of the signal, calculates a time difference, and subsequently calculates a cable length. The master unit and the slave unit communicate via the Lora communication module; interactive operations are performed through the human-machine interface module.

The MCU module uses an LPC1778 chip, and the time calibration module uses a 200 MHz crystal oscillator.

A precise fault location method for a collector line in an onshore wind farm includes the following steps:
1) A slave unit inputs a high-voltage pulse signal S3 at the beginning of a cable, where the high-voltage pulse signal S3 is reflected back to the slave unit after encountering a fault point, calculates a time difference between input and reception of the pulse signal S3 by the slave unit, and multiplies a wave speed by the time difference to obtain a cable length L1 at the fault point.
2) The slave unit inputs a high-voltage pulse signal S1 at the beginning of the cable, with an input time of the high-voltage pulse signal S1 denoted as T1.
3) A master unit at a measurement point receives the high-voltage pulse signal S1, with a reception time of the high-voltage pulse signal S1 denoted as T1′.
4) The master unit inputs a pulse signal S2 after receiving the pulse signal S1, with an input time of the pulse signal S2 denoted as T2′.
5) The slave unit receives the pulse signal S2, with a reception time of the pulse signal S2 denoted as T2.
6) Calculate a time difference Δt₂ between the input of the pulse signal S1 and the reception of the pulse signal S2 by the slave unit; calculate a time difference Δt₁ between the reception of the pulse signal S1 and the input of the pulse signal S2 by the master unit; and calculate a cable length L2 at the measurement point and obtain a corresponding geographical location.

Δt₁=T2′−T1′, and Δt₂=T2−T1. A traveling wave acquisition and calculation terminal uses Lora communication to receive the time difference, and calculates a length from any point on the cable to the beginning of the cable using the following formula: L=v(Δt₂−Δt₁)/2, where L is the cable length L2 at the measurement point, and v represents a propagation speed of the high-voltage pulse signal in the cable, known as the wave speed.

T1′-T1 and T2-T2′ are the time differences between the master and slave units. The time reference for T1 and T2 is TO, and the time reference for T1′ and T2′ is TO′. In complex scenarios, TO and TO′ are not synchronized, leading to significant deviations. T2-T1 and T2′-T1′ are internal time differences of the apparatus, and the internal time accuracy of the apparatus is only affected by internal clocks. High-precision crystal oscillators can be used to enhance time accuracy, without the need to use Beidou/GPS timing for time calibration, thereby further improving distance measurement accuracy.
7) If L2 is not equal to L1, move the master unit by 2 to 3 approaches, to make L2 equal to L1, where in this case, a position of the master unit is a geographical location of the fault point.

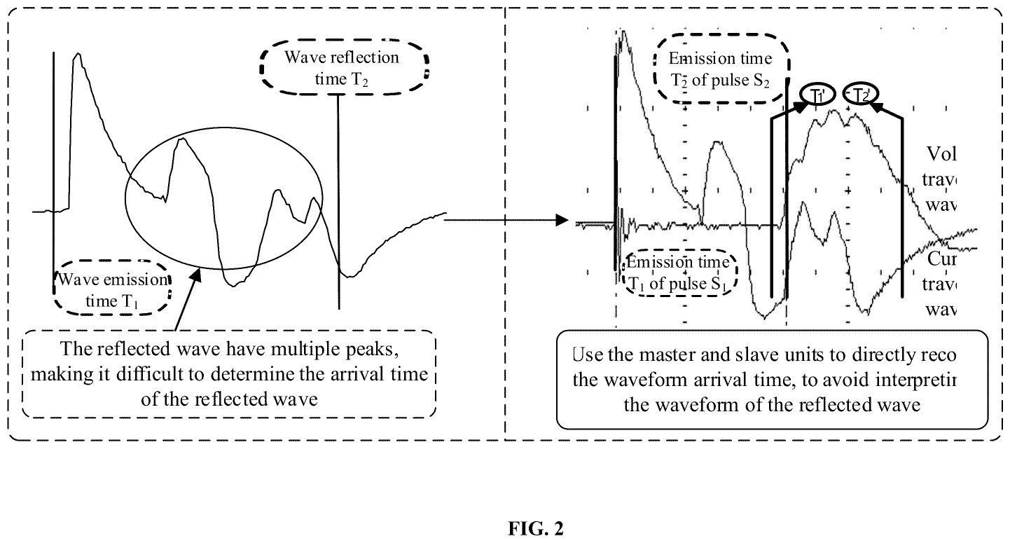

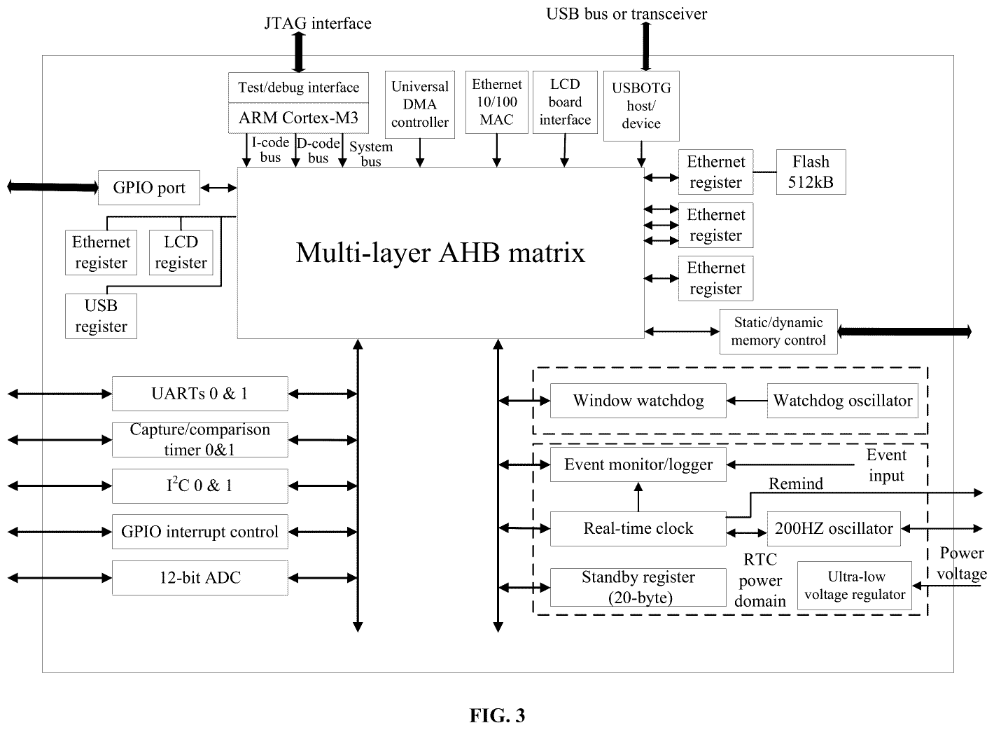

As shown in FIG. 2, precise distance measurement is achieved through the coordinated emission of voltage traveling waves by the slave unit and current traveling waves by the master unit. It can be learned from FIG. 2 that the dual-wave coordination model uses two unidirectional pulses instead of a reflected wave model. The time at which the slave unit emits a pulse to the master unit is denoted as T1, the time at which the master unit receives the pulse is denoted as T1′, the time at which the master unit emits a pulse to the slave unit is denoted as T2, and the time at which the slave unit receives the pulse is denoted as T2′. Directly recording the waveform arrival times using the master and slave units effectively avoids interpreting reflected waves, thereby enhancing distance measurement accuracy in multi-branch scenarios.

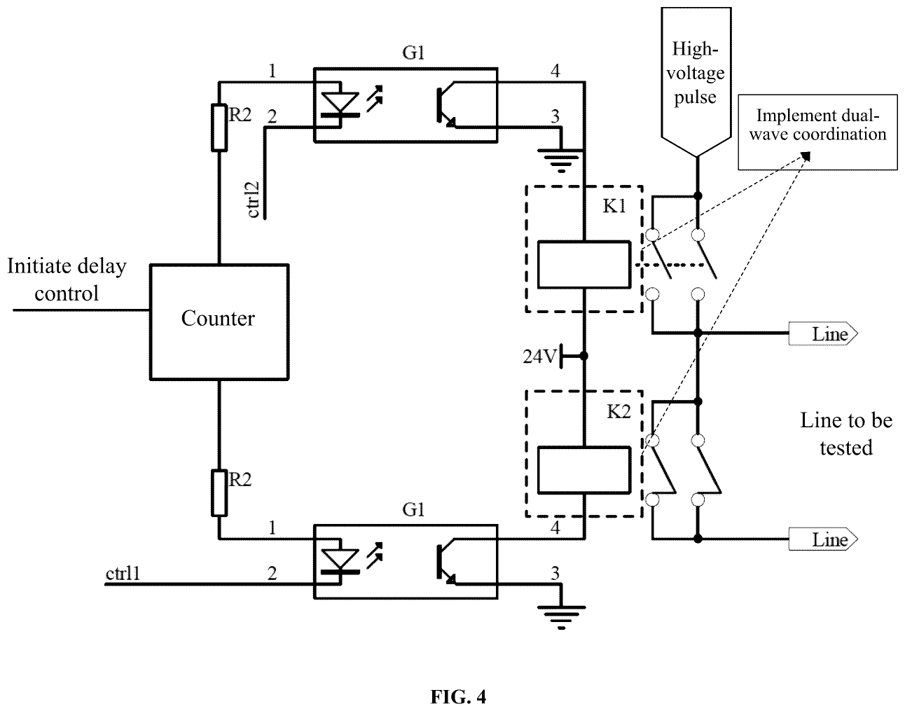

FIG. 4 is a circuit diagram of a dual-wave coordination module according to the present disclosure. K1 and K2 are electronic devices that achieve dual-wave coordination. During input of pulse signals into the cable, K1 and K2 act, and the high-voltage pulse output module inputs high-frequency pulse signals into the cable. The signal detection circuit, upon detecting the signal S1, initiates a delay loop, the counter starts counting, and when a preset time is reached, K1 and K2 return to provide a path for the signal S2, ensuring that the detection circuit can detect the signal S2.

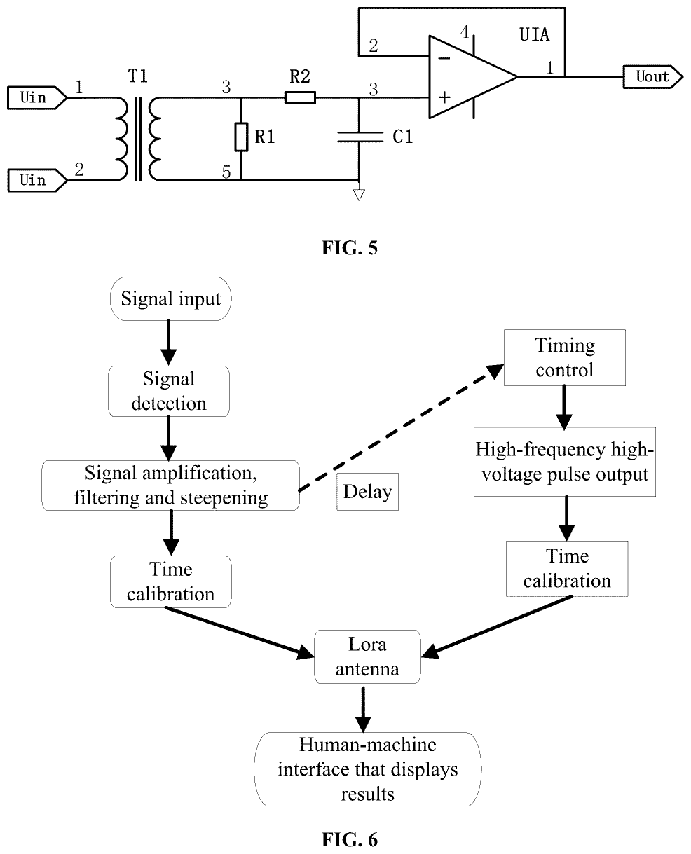

FIG. 5 is a circuit diagram of a signal amplification, filtering, and steepening module according to the present disclosure. T1 is a high-frequency pulse current transformer that isolates low-frequency signals, separating strong and weak electricity. Since T1 reflects dI/dt, it acts on steepening waveforms. U1 is a voltage follower that improves signal input impedance and load capacity.

As shown in FIG. 7, the slave unit triggers the emission of a voltage wave S₁ and records the trigger time T₁. S₁ propagates in the cable to reach the measurement point. The acquisition and calculation terminal of the master unit detects and marks the arrival time of S₁ as T₁′. The master unit triggers the emission of a current wave S₂ and records the trigger time T₂′. S₂ propagates in the cable to reach the measurement point. The acquisition and calculation terminal of the slave unit detects and marks the arrival time of S₂ as T₂. The master and slave units separately calculate the corresponding time differences Δt₁ and Δt₂. The traveling wave acquisition and calculation terminal uses Lora communication to receive the time differences, and calculates a length from any point on the cable to the beginning of the cable using the following formula: L=v(Δt₂−Δt₁)/2.

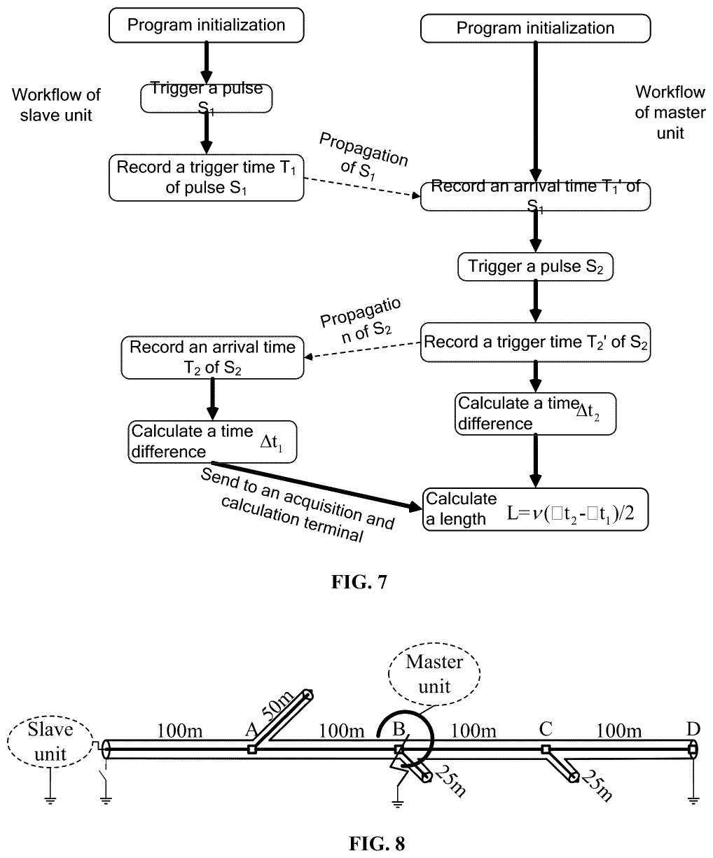

As shown in FIG. 8, fault points were set artificially and different transition resistances were added at the fault points to simulate the waveform transmission process during real faults; a collector line structure with multiple branches was constructed using coaxial cables. The main experimental steps are as follows:
Step 1: Set fault points. As shown in FIG. 8, in one set of experiments, a fault point was set at point B, connecting the cable conductor and cable shielding layer. Transition resistors were serially connected at the fault point to simulate single-phase ground faults under different impedances, with resistor values set at 50 Ω, 470 Ω, 1 kΩ, 2 kΩ, 5.1 kΩ, and 10 kΩ. Additionally, another set of experiments without setting fault points were included.
Step 2: Connect a master unit and a slave unit of a cable length meter. An output end of the slave unit was connected to the beginning of the cable, and an output end of the master unit was set at the measurement point using a sensor.
Step 3: Set sampling points of an oscilloscope. Sampling points were set at the beginning of the power cable and the measurement point. The oscilloscope software was turned on for waveform recording, with oscilloscope channel 1 collecting the waveform at the beginning of the cable and oscilloscope channel 2 collecting the waveform at the main measurement point.
Step 4: Set a wave speed v. The wave speed was set based on the basic cable parameters provided by the cable manufacturer. For example, for the SYV75 coaxial cable used in the experiment, the cable manufacturer provided a cable transmission speed ratio of 66 (+/−3) %. Considering waveform dispersion, a recommended value was 65% C=195 m/us. Alternatively, the wave speed can be obtained by measurement on a cable with a known cable length. A cable length meter was set up at the beginning and end of the known cable to measure a distance, and the measured distance was compared with a known distance to obtain the wave speed. In the experiments in the present disclosure, the wave speed was set at 190 m/us.
Step 5: Record measurement data. Pulse input switches of the master and slave units of the apparatus were turned on. The cable length meter automatically measured the cable length every 30 seconds, with the measured data displayed on the upper computer. Data from four cable measurements can be displayed, and an average of the four measurements was current cable length data.

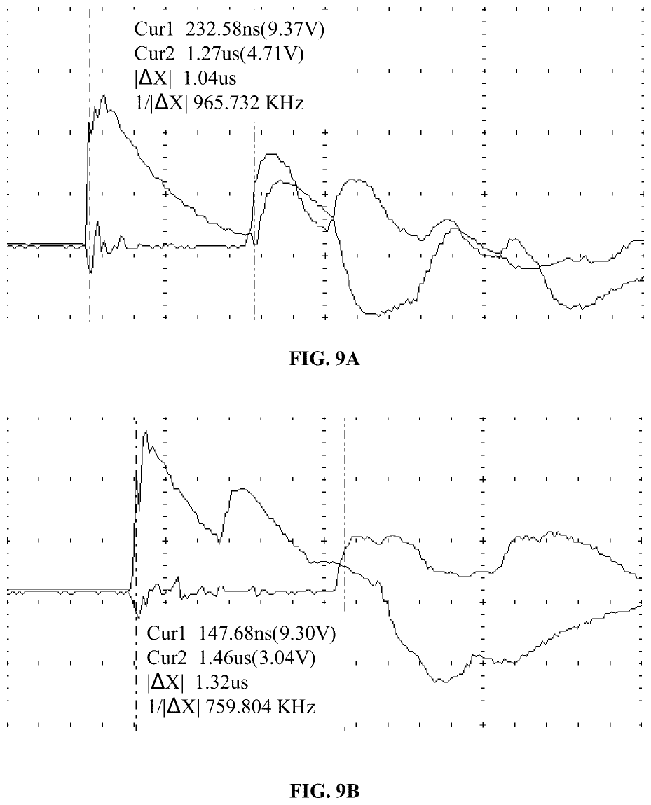

As shown in FIGS. 9A-9B, two sets of indoor experiments were conducted.
Experiment 1: The fault point was set at point B, a wave speed was 190 m/us, and an actual cable length was 203 m. The experiment results are shown in Table 1, with the pulse signal waveform as depicted in FIG. 9A. In FIGS. 9A-9B, the time marked by cur1 is the input time of the pulse signal S1, the time marked by cur2 is the time at which the pulse signal reaches the master unit, and |ΔX| represents a time difference for the pulse signal S1 to propagate from the beginning of the cable to the measurement point. The absolute error is a difference between a fixed point distance and the actual cable length.

TABLE 1
Data of Experiment 1

| | Fault point | Cable | Location | Absolute |
|---|---|---|---|---|
| No. | resistance(Ω) | length (m) | distance (m) | error (m) |
| 1 | * | 203 | 200.95 | −2.05 |
| 2 | 50 | 203 | 200.45 | −2.55 |
| 3 | 470 | 203 | 200.37 | −2.63 |
| 4 | 1k | 203 | 200.225 | −2.775 |
| 5 | 2k | 203 | 200.2 | −2.8 |
| 6 | 5.1k | 203 | 199.975 | −3.025 |
| 7 | 10k | 203 | 200.283 | −2.717 |

(* indicates that no fault is set)

Experiment 2: The fault point was set at point C, a wave speed was 190 m/us, and an actual cable length was 253 m. The experiment results are shown in Table 2, with the pulse signal waveform as depicted in FIG. 9B.

TABLE 2
Data of Experiment 2

| | Fault point | Cable | Location | Absolute |
|---|---|---|---|---|
| No. | resistance(Ω) | length (m) | distance (m) | error (m) |
| 1 | * | 253 | 251.8 | −1.2 |
| 2 | 50 | 253 | 250.75 | −2.25 |
| 3 | 470 | 253 | 251.675 | −1.325 |
| 4 | 1k | 253 | 251.5 | −1.5 |
| 5 | 2k | 253 | 251.375 | −1.625 |
| 6 | 5.1k | 253 | 251.68 | −1.32 |
| 7 | 10k | 253 | 251.7 | −1.3 |

(* indicates that no fault is set)

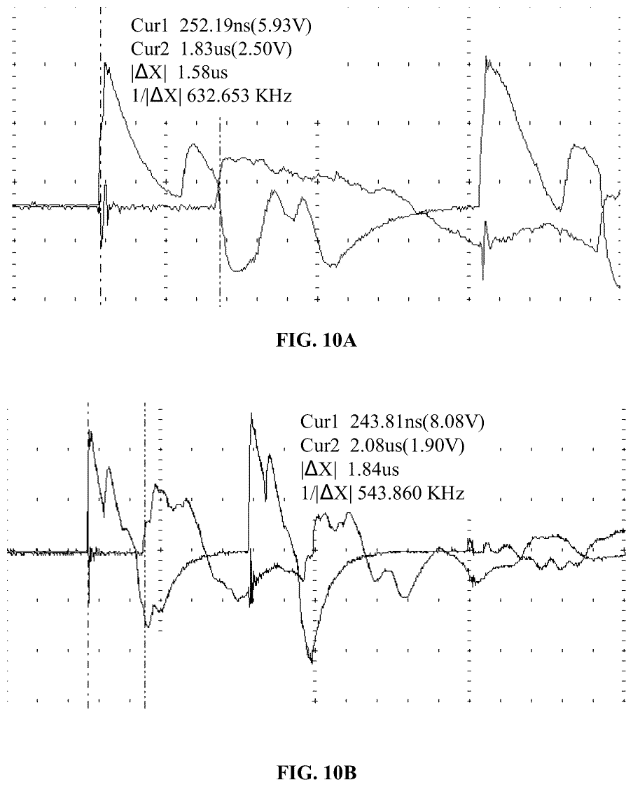

As shown in FIGS. 10A-10B, two sets of outdoor experiments were conducted in the present disclosure.

Experiment 3: The fault point was set at point C, a wave speed was 190 m/us, and an actual cable length was 303 m. The experiment results are shown in Table 3, with the pulse signal waveform as depicted in FIG. 10A.

TABLE 3
Data of Experiment 3

| | Fault point | Cable | Location | Absolute |
|---|---|---|---|---|
| No. | resistance(Ω) | length (m) | distance (m) | error (m) |
| 1 | * | 303 | 300.9 | −2.1 |
| 2 | 50 | 303 | 300.65 | −2.35 |
| 3 | 470 | 303 | 300.65 | −2.35 |
| 4 | 1k | 303 | 301.3 | −1.7 |
| 5 | 2k | 303 | 301.575 | −1.425 |
| 6 | 5.1k | 303 | 300.875 | −2.125 |
| 7 | 10k | 303 | 301.7 | −1.3 |

(* indicates that no fault is set)

Experiment 4: The fault point was set at point D, a wave speed was 190 m/us, and an actual cable length was 353 m. The experiment results are shown in Table 4.

TABLE 4
Data of Experiment 4

| | Fault point | Cable | Location | Absolute |
|---|---|---|---|---|
| No. | resistance(Ω) | length (m) | distance (m) | error (m) |
| 1 | * | 353 | 350.5 | −2.5 |
| 2 | 50 | 353 | 350.05 | −2.95 |
| 3 | 470 | 353 | 350.675 | −2.325 |
| 4 | 1k | 353 | 350.075 | −2.925 |
| 5 | 2k | 353 | 350.575 | −2.425 |
| 6 | 5.1k | 353 | 350.75 | −2.25 |
| 7 | 10k | 353 | 351.25 | −1.75 |

(* indicates that no fault is set)

The pulse signal waveform is shown in FIG. 10B.

1. A precise fault location apparatus for a collector line in an onshore wind farm, comprising:
a slave unit installed at the beginning of a collector line cable and being configured to: input a high-voltage pulse signal S3 into a collector line; record an output time of the high-voltage pulse signal S3 and a time at which the high-voltage pulse signal S3 reaches the slave unit after being reflected from a fault point; calculate a time difference, and then multiply a wave speed by the calculated time difference to obtain a cable length at a fault point; and the slave unit being further configured to: input a high-voltage pulse signal S1 into the collector line; receive a high-voltage pulse signal S2 inputted by a master unit; and detect an input time of the high-voltage pulse signal S1 as well as a reception time of the high-voltage pulse signal S2; and
the master unit being installed at a measurement point near the fault point of the collector line cable and configured to: receive the high-voltage pulse signal S1 inputted by the slave unit; output the high-voltage pulse signal S2 to the slave unit; and detect a reception time of the high-voltage pulse signal S1 as well as an output time of the high-voltage pulse signal S2.

2. The precise fault location apparatus for a collector line in an onshore wind farm according to claim 1, wherein the master unit and the slave unit each comprises:
a microcontroller unit (MCU) module,
a time calibration module,
a signal detection module,
a timing control module,
a signal amplification, filtering, and steepening module,
a Lora communication module,
a high-frequency high-voltage pulse power output module, and
a human-machine interface module;
the MCU module is connected to the time calibration module, the signal detection module, the timing control module, the signal amplification, filtering, and steepening module, the Lora communication module, the lightweight high-frequency high-voltage pulse power output module, and the human-machine interface module;
the high-frequency high-voltage pulse power output module is connected to the signal amplification, filtering, and steepening module; and
the MCU module outputs a high-voltage pulse signal through a high-frequency high-voltage pulse power, and the high-voltage pulse signal is strengthened through the signal amplification, filtering, and steepening module and is output;
the timing control module records an output time of the signal, and the signal detection module records a time at which the signal reaches the slave unit; the MCU module controls the output time of the signal, calculates a time difference, and subsequently calculates a cable length;
the master unit and the slave unit communicate via the Lora communication module; and
interactive operations are performed through the human-machine interface module.

3. The precise fault location apparatus for a collector line in an onshore wind farm according to claim 2, wherein the MCU module uses an LPC1778 chip, and the time calibration module uses a 200 MHz crystal oscillator.

4. A precise fault location method for a collector line in an onshore wind farm based on the precise fault location apparatus for a collector line in an onshore wind farm according to claim 1, comprising the following steps:
1) inputting, by a slave unit, a high-voltage pulse signal S3 at the beginning of a cable, wherein the high-voltage pulse signal S3 is reflected back to the slave unit after encountering a fault point;
calculating a time difference between input and reception of the pulse signal S3 by the slave unit; and multiplying a wave speed by the time difference to obtain a first cable length L1 at the fault point;
2) inputting, by the slave unit, a high-voltage pulse signal S1 at the beginning of the cable, with an first input time T1 of the high-voltage pulse signal S1;
3) receiving, by a master unit at a measurement point, the high-voltage pulse signal S1, with a first reception time T1′ of the high-voltage pulse signal S1;
4) inputting, by the master unit, a high-voltage pulse signal S2 after receiving the high-voltage pulse signal S1, with a second input time T2′ of the high-voltage pulse signal S2;
5) receiving, by the slave unit, the high-voltage pulse signal S2, with a second reception time T2 of the high-voltage pulse signal S2;
6) calculating a time difference Δt₂ between the input of the high-voltage pulse signal S1 and the reception of the high-voltage pulse signal S2 by the slave unit; calculating a time difference Δt₁ between the reception of the high-voltage pulse signal S1 and the input of the high-voltage pulse signal S2 by the master unit; and calculating a second cable length at the measurement point and obtaining a corresponding geographical location; and
7) if the second cable length L2 is not equal to the first cable length L1, moving the master unit 2 to 3 times, to make the second cable length L2 equal to first cable length L1, whereby, a position of the master unit is a geographical location of the fault point.

5. The precise fault location method for a collector line in an onshore wind farm according to claim 4, wherein in step 6), Δt₁=T2′−T1′, and Δt₂=T2−T1; a traveling wave acquisition and calculation terminal uses Lora communication to receive the time difference, and calculates a length from any point on the cable to the beginning of the cable using the following formula: L=v(Δt₂−Δt₁)/2, wherein L is the second cable length L2 at the measurement point, and v represents a propagation speed of the high-voltage pulse signal in the cable, known as the wave speed.

6. The precise fault location method for a collector line in an onshore wind farm according to claim 4, wherein the master unit and the slave unit each comprises:
a microcontroller unit (MCU) module,
a time calibration module,
a signal detection module,
a timing control module,
a signal amplification,
a filtering, and steepening module,
a Lora communication module,
a high-frequency high-voltage pulse power output module, and
a human-machine interface module;
the MCU module is connected to the time calibration module, the signal detection module, the timing control module, the signal amplification, filtering, and steepening module, the Lora communication module, the lightweight high-frequency high-voltage pulse power output module, and the human-machine interface module;
the high-frequency high-voltage pulse power output module is connected to the signal amplification, filtering, and steepening module; and
the MCU module outputs a high-voltage pulse signal through a high-frequency high-voltage pulse power, and the high-voltage pulse signal is strengthened through the signal amplification, filtering, and steepening module and is output;
the timing control module records an output time of the signal, and the signal detection module records a time at which the signal reaches the slave unit; the MCU module controls the output time of the signal, calculates a time difference, and subsequently calculates a cable length;
the master unit and the slave unit communicate via the Lora communication module;
interactive operations are performed through the human-machine interface module.

7. The precise fault location method for a collector line in an onshore wind farm according to claim 6, wherein the MCU module uses an LPC1778 chip, and the time calibration module uses a 200 MHz crystal oscillator.

8. The precise fault location method for a collector line in an onshore wind farm according to claim 6, wherein in step 6), Δt₁=T2′−T1′, and Δt₂=T2−T1; a traveling wave acquisition and calculation terminal uses Lora communication to receive the time difference, and calculates a length from any point on the cable to the beginning of the cable using the following formula: L=v(Δt₂−Δt₁)/2, wherein L is the second cable length L2 at the measurement point, and v represents a propagation speed of the high-voltage pulse signal in the cable, known as the wave speed.

9. The precise fault location method for a collector line in an onshore wind farm according to claim 7, wherein in step 6), Δt₁=T2′−T1′, and Δt₂=T2−T1; a traveling wave acquisition and calculation terminal uses Lora communication to receive the time difference, and calculates a length from any point on the cable to the beginning of the cable using the following formula: L=v(Δt₂−Δt₁)/2, wherein L is the second cable length L2 at the measurement point, and v represents a propagation speed of the high-voltage pulse signal in the cable, known as the wave speed.
